(19) United States
(12) Patent Application Publication
(10) Pub. No.: US 2025/0105590 A1
(43) Pub. Date: Mar. 27, 2025

(54) MULTIMODE LASER

(71) Applicant: Mitsubishi Electric Corporation, Tokyo (JP)

(72) Inventors: Nobuo OHATA, Tokyo (JP); Nobuhiko NISHIYAMA, Tokyo (JP)

(73) Assignee: Mitsubishi Electric Corporation, Tokyo (JP)

(21) Appl. No.: 18/975,748

(22) Filed: Dec. 10, 2024

Related U.S. Application Data
(63) Continuation of application No. PCT/JP2022/026538, filed on Jul. 4, 2022.

(51) Int. Cl. H01S 5/14; H01S 5/00; H01S 5/065; H01S 5/10

(52) U.S. Cl. CPC H01S 5/14; H01S 5/0071; H01S 5/0653; H01S 5/101

(57) ABSTRACT

A multimode laser includes a semiconductor amplifier, a laser resonator constituted between a loop mirror including a waveguide formed on a semiconductor substrate and the semiconductor amplifier, in which a characteristic shape of reflectance of the loop mirror is a convex shape in an oscillation wavelength range.

### CROSS REFERENCE TO RELATED APPLICATION

This application is a Continuation of PCT International Application No. PCT/JP2022/026538, filed on Jul. 4, 2022, which is hereby expressly incorporated by reference into the present application.

### TECHNICAL FIELD

The present disclosure relates to a multimode laser.

### BACKGROUND ART

With an increase in capacity of optical communication in recent years, an optical communication module employing a wavelength division multiplexing (hereinafter referred to as WDM) system has become widespread. For example, a multimode laser is used as the optical communication module. The multimode laser is a laser device that emits a multimode laser beam. For example, Non Patent Literature 1 describes a multimode laser in which a gain medium and a device (hereinafter referred to as a silicon photonics device) produced by silicon photonics technology are combined in order to achieve miniaturization of an optical communication module.

### CITATION LIST

### Non Patent Literature

Non Patent Literature 1: Nami Yasuoka, et al., “External-Cavity Quantum-Dot Laser with Silicon Photonics Waveguide Mirror for Four-Wavelength Simultaneous Oscillation with an 800 GHz Channel Spacing,” ISLC2016 ThA2.

### SUMMARY OF INVENTION

### Technical Problem

In the multimode laser described in Non Patent Literature 1, there is a problem that power efficiency is reduced due to generation of laser oscillation outside a predetermined oscillation wavelength range.

The present disclosure solves the above problem, and an object of the present disclosure is to obtain a multimode laser capable of suppressing laser oscillation outside an oscillation wavelength range and increasing power efficiency.

### Solution to Problem

A multimode laser according to the present disclosure includes a semiconductor amplifier; and a laser resonator constituted between a loop mirror including a waveguide formed on a substrate and the semiconductor amplifier, wherein a characteristic shape of reflectance of the loop mirror is a convex shape in an oscillation wavelength range, and the loop mirror includes a first directional coupler including waveguides adjacent to each other, a second directional coupler having a same waveguide width as the first directional coupler, a pair of waveguides provided between the first directional coupler and the second directional coupler, one of the waveguides being a bent waveguide, and a loop waveguide optically coupled to the second directional coupler.

### Advantageous Effects of Invention

According to the present disclosure, a laser resonator is constituted between a semiconductor amplifier and a loop mirror, and a reflectance characteristic shape of the loop mirror is a convex shape in an oscillation wavelength range. The oscillation of a laser beam having a wavelength outside an oscillation wavelength range is suppressed, and thus the multimode laser according to the present disclosure can suppress laser oscillation outside the oscillation wavelength range and can increase power efficiency.

### BRIEF DESCRIPTION OF DRAWINGS

FIG. 1 is a perspective view illustrating a multimode laser according to a first embodiment.

FIG. 2 is a plan view illustrating a loop mirror in the first embodiment.

FIGS. 3A and 3B are diagrams illustrating characteristics of a conventional multimode laser.

FIGS. 4A and 4B are diagrams illustrating characteristics of the multimode laser according to the first embodiment.

FIG. 5 is a plan view illustrating Modification (1) of the loop mirror in the first embodiment.

FIG. 6 is a plan view illustrating Modification (2) of the loop mirror in the first embodiment.

FIG. 7 is a perspective view illustrating a multimode laser according to a second embodiment.

FIG. 8 is a graph illustrating a reflection characteristic of a loop mirror in the second embodiment.

FIG. 9 is a plan view illustrating Modification (1) of the loop mirror in the second embodiment.

FIG. 10 is a plan view illustrating Modification (2) of the loop mirror in the second embodiment.

FIG. 11 is a plan view illustrating Modification (3) of the loop mirror in the second embodiment.

### DESCRIPTION OF EMBODIMENTS

### First Embodiment

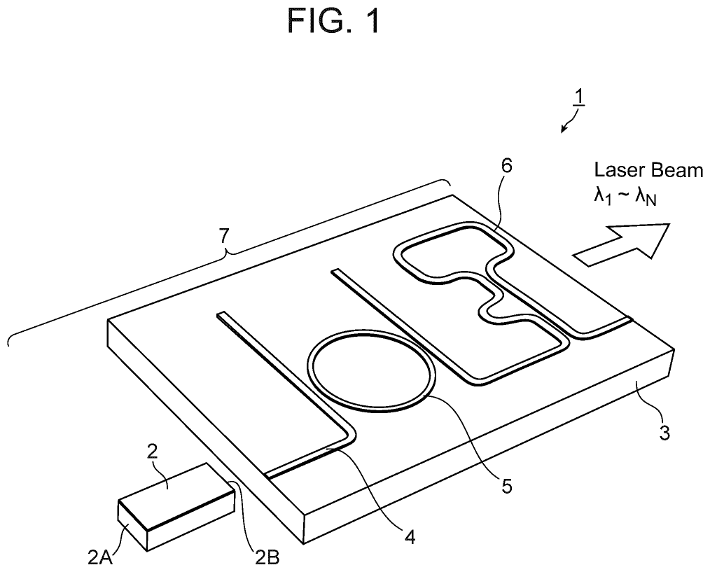

FIG. 1 is a perspective view illustrating a multimode laser 1 according to a first embodiment. The multimode laser 1 is a laser that emits a laser beam having wavelengths λᵢ to λ_{N} in a desired oscillation wavelength range. N is an integer of 2 or more. As illustrated in FIG. 1, a multimode laser 1 includes a semiconductor amplifier 2 and a semiconductor substrate 3. The semiconductor amplifier 2 amplifies the laser beam. Waveguides 4 are formed on the semiconductor substrate 3, and waveguides 4 constitute a ring resonance filter 5 and a loop mirror 6. A laser resonator 7 of the multimode laser 1 is constituted between the semiconductor amplifier 2 and the loop mirror 6 provided on the semiconductor substrate 3.

High reflection (HR) coating is applied to a rear surface 2A of the semiconductor amplifier 2 (surface opposite to the emission surface 2B of the laser beam). In the rear surface 2A to which the HR coating is applied, high reflectance is obtained in a wide wavelength band including the desired oscillation wavelength range. Furthermore, anti-reflection (AR) coating is applied to the emission surface 2B of the laser beam in the semiconductor amplifier 2. The reflection of the laser beam on the emission surface 2B can be made substantially zero by the AR coating. By causing a current to flow through the semiconductor amplifier 2, a spontaneous emission generated in the semiconductor amplifier 2 as a seed is amplified. In addition, the emission surface 2B of the semiconductor amplifier 2 is optically coupled to an end of the waveguide 4 formed on the semiconductor substrate 3.

As the semiconductor amplifier 2, for example, a semiconductor amplifier (hereinafter referred to as a quantum dot semiconductor amplifier) including an active layer of quantum dots is used. The quantum dot semiconductor amplifier is an amplifier having less noise superimposed on the laser beam for each oscillation wavelength, and thus is suitable for the multimode laser 1. Note that other types of semiconductor amplifiers can also be used for the multimode laser 1. For example, a quantum well semiconductor amplifier may be used as the semiconductor amplifier 2.

The semiconductor substrate 3 is a substrate on which waveguides for propagating light are formed. The semiconductor substrate 3 is provided with the waveguide 4 functioning as a transmission path of light, and also with the ring resonance filter 5 and the loop mirror 6 constituted by waveguides. The semiconductor substrate 3 is, for example, a silicon substrate, and the waveguide 4, the ring resonance filter 5, and the loop mirror 6 are constituted by silicon waveguides using the silicon photonics technology. Note that a silicon nitride (SiN) substrate may be used for the semiconductor substrate 3. In addition, the waveguide may be an organic waveguide.

The ring resonance filter 5 passes light (laser beam having wavelengths λ₁ to λ_{N}) at predetermined wavelength intervals from the desired oscillation wavelength range. For example, the ring resonance filter 5 emits a laser beam at wavelength intervals for optical communication. Note that, when the ring resonance filter 5 is not provided, light having several tens of thousands of wavelengths is generated between the wavelengths of output light, and output power is dispersed.

In the multimode laser 1, Fabry-Perot resonance occurs between the rear surface 2A functioning as an HR mirror that substantially totally reflects spontaneous emission light generated by applying a current to the semiconductor amplifier 2 as a seed and the loop mirror 6 whose characteristic shape of reflectance is a convex shape in the desired oscillation wavelength range. Light of a wavelength that can be passed is determined by the ring resonance filter 5 in the laser resonator 7, and only the light of the passing wavelength oscillates by laser oscillation.

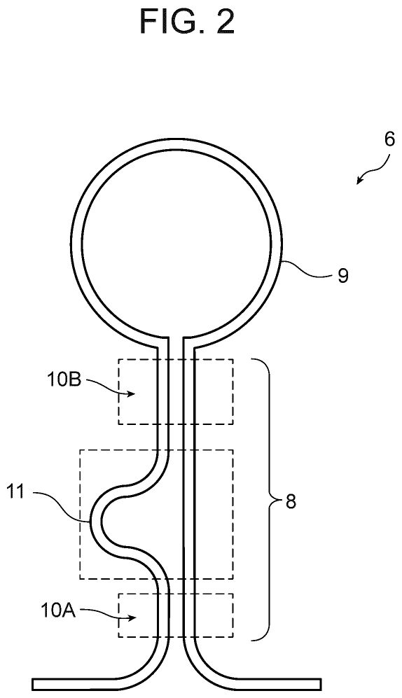

As does the ring resonance filter 5, the loop mirror 6 includes a waveguide formed on the semiconductor substrate 3, and constitutes the laser resonator 7 with the semiconductor amplifier 2. FIG. 2 is a plan view illustrating the loop mirror 6 according to the first embodiment. As illustrated in FIG. 2, the loop mirror 6 is a Sagnac loop mirror including a Mach-Zehnder interferometer (hereinafter referred to as an MZ interferometer) 8 and a loop waveguide 9.

The MZ interferometer 8 includes a directional coupler 10A, a directional coupler 10B, and a pair of waveguides including a bent waveguide 11. The loop waveguide 9 is a waveguide formed in a loop shape, and is optically coupled to the directional coupler 10B. As surrounded by a broken line in FIG. 2, the directional coupler 10A is a first directional coupler including waveguides adjacent to each other and having the same width. The directional coupler 10B is a second directional coupler having the same waveguide width as the directional coupler 10A, and includes waveguides adjacent to each other and having the same width. Further, in the directional coupler 10A and the directional coupler 10B, lengths of the waveguides are different from each other. For example, as illustrated in FIG. 2, the directional coupler 10B is formed to be longer than the directional coupler 10A. However, the lengths of the waveguides of the directional coupler 10A and the directional coupler 10B may be the same. In the pair of waveguides provided between the directional coupler 10A and the directional coupler 10B, one of the waveguides is the bent waveguide 11.

In the pair of waveguides in FIG. 2, the waveguide on the left side in the drawing is the bent waveguide 11, but the waveguide on the right side in the drawing may be a bent waveguide. In addition, although FIG. 2 illustrates the bent waveguide 11 having one bending portion, it may be a bent waveguide having a plurality of bent portions, or both waveguides of the pair of waveguides may be bent waveguides. For example, in a case where the waveguide on the left side of the drawing is a bent waveguide bent to the right and the waveguide on the right side of the drawing is a bent waveguide bent to the right, it is sufficient if the lengths of the left and right bent waveguides are different from each other. That is, it is sufficient if a difference occurs in light propagation characteristics in the left and right waveguides of the pair of waveguides and the difference is a desired value. By configuring the loop mirror 6 in this manner, the characteristic shape of the reflectance of the loop mirror 6 can be a convex shape in the desired oscillation wavelength range.

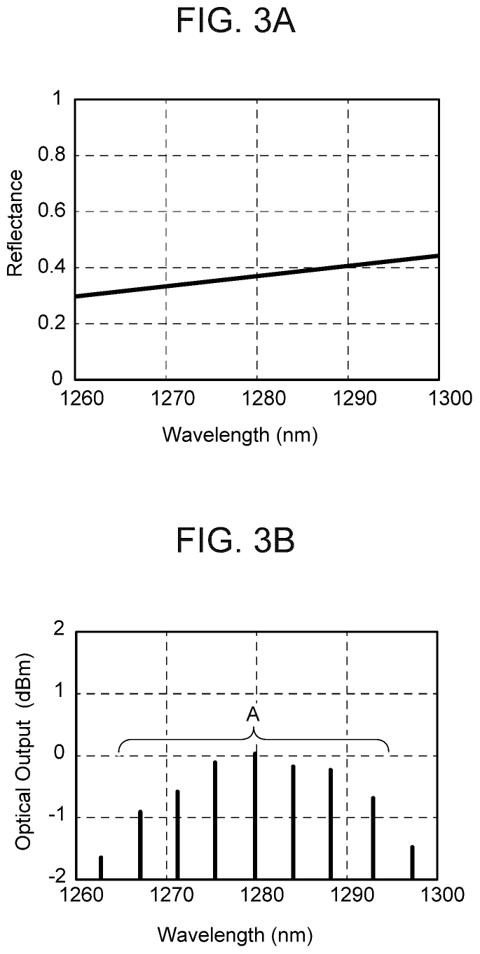

FIG. 3A is a graph illustrating a reflection characteristic of a loop mirror in a conventional multimode laser, and illustrates a reflection characteristic of a conventional general loop mirror. FIG. 3B is a graph illustrating laser oscillation characteristics of a conventional multimode laser, and illustrates a result of simulating laser oscillation characteristics of a laser resonator constituted between a loop mirror having the reflection characteristics of FIG. 3A and a semiconductor amplifier. Note that the laser resonance is Fabry-Perot resonance in which spontaneous emission light generated by applying a current of 100 mA to the semiconductor amplifier is used as a seed.

As illustrated in FIG. 3A, the conventional general loop mirror has a reflection characteristic with a substantially constant reflectance with respect to a wavelength. For example, in the multimode laser described in Non Patent Literature 1, a wavelength interval of light resonated between the semiconductor amplifier as the gain medium and the loop mirror is determined by a resonator filter. Further, in the laser resonator, when the loop mirror returns light to the semiconductor amplifier, the light is amplified and laser oscillation is performed. When the reflectance for returning light to the semiconductor amplifier is small, the optical output power that can be extracted from the end of the loop mirror increases. However, when the reflectance of the loop mirror is too small, a sufficient photon density cannot be obtained, and laser oscillation does not occur.

As illustrated in FIG. 3A, the conventional loop mirror has a substantially constant reflectance for all wavelengths determined by the resonator filter, so that a substantially constant gain is given to light of all the wavelengths determined by the resonator filter in the laser resonator. Thus, in the conventional multimode laser, light in a wide wavelength range including the wavelength determined by the resonator filter resonates, and the laser oscillation characteristic becomes an oscillation characteristic corresponding to the gain shape of the semiconductor amplifier as illustrated in FIG. 3B. Accordingly, light having a wavelength outside an oscillation wavelength range A also oscillates, and power efficiency decreases.

On the other hand, the multimode laser 1 includes the loop mirror 6 in which the characteristic shape of the reflectance is a convex shape in the desired oscillation wavelength range A, thereby preventing light having a wavelength outside the oscillation wavelength range A from oscillating. Thus, in the semiconductor amplifier 2, a carrier is used for light amplification on the oscillating wavelength side, uniform laser oscillation with a small difference in optical output between wavelengths in the oscillation wavelength range A can be achieved.

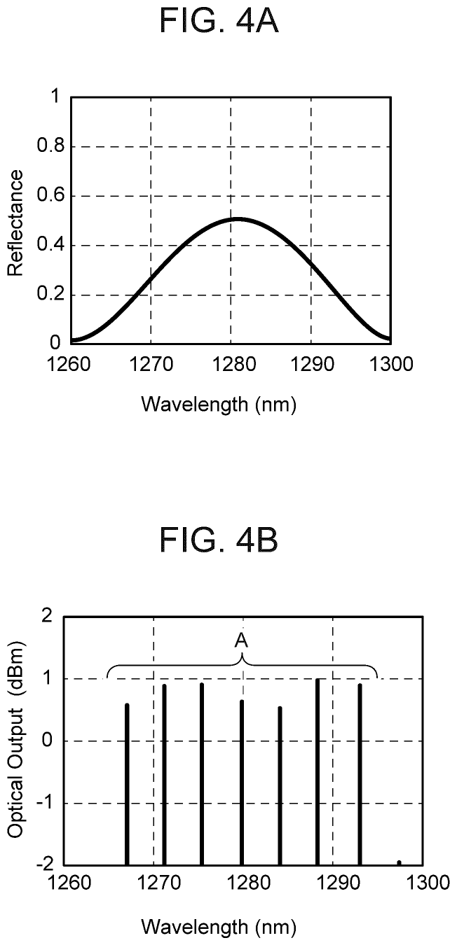

FIG. 4A is a graph illustrating a reflection characteristic of the loop mirror 6 in the multimode laser 1 according to the first embodiment. FIG. 4B is a graph illustrating laser oscillation characteristics of the multimode laser 1, and illustrates a simulation result of the laser oscillation characteristics of the laser resonator 7 constituted between the loop mirror 6 having the reflection characteristic of FIG. 4A and the semiconductor amplifier 2. Note that the laser resonance is Fabry-Perot resonance in which spontaneous emission light generated by applying a current of 100 mA to the semiconductor amplifier 2 is used as a seed.

In a case where the loop mirror 6 has the reflection characteristic illustrated in FIG. 4A, reflectance for light having a wavelength of less than 1265 nm and light having a wavelength of more than 1295 nm is small, and transmittance, which is the ratio at which light is transmitted from the loop mirror 6, is increased accordingly. At this time, laser oscillation does not occur in the laser resonator 7, and the optical output from the laser resonator 7 also increases.

On the other hand, for the range from 1265 nm to 1295 nm, which is the desired oscillation wavelength range A, reflectance of the loop mirror 6 is equal to or higher than the reflectance in the same range illustrated in FIG. 3A, and the transmittance of the loop mirror 6 decreases accordingly, so that output from the laser resonator 7 is reduced and laser resonance occurs.

Light having a wavelength at which the reflectance of the loop mirror 6 is large has a large gain of the semiconductor amplifier 2, and light having a wavelength at which the reflectance of the loop mirror 6 is small has a small gain of the semiconductor amplifier 2. In a case where the gain is larger than a loss of light in the laser resonator 7, the light resonates and is not output from the laser resonator 7, and the light having a gain smaller than the loss is output from the laser resonator 7 without resonating.

That is, in the laser resonator 7, when the subtraction between the gain of the semiconductor amplifier 2 and the total loss becomes negative, oscillation is not performed, and when the subtraction becomes positive, oscillation occurs. In the convex shape of the reflection characteristic of the loop mirror 6, a bottom portion having a small reflectance has a small gain, so that the optical output increases without oscillation. Since light having a wavelength corresponding to the vicinity of the apex having a large reflectance has a large gain, the light is strongly oscillated in the laser resonator 7.

The ratio at which the light having the wavelength corresponding to the vicinity of the apex having the large reflectance is output is determined by the transmittance of the loop mirror 6, and thus the optical output can be made uniform by adjusting the transmittance of the loop mirror 6 with respect to the light having each wavelength. Note that, ideally, the relationship of transmittance=1−reflectance is established, so that the transmittance of the loop mirror 6 can be set from the reflectance.

Further, the loop mirror 6 illustrated in FIG. 2 changes the phase of light propagating through the waveguide to make the characteristic shape of the reflectance a convex shape. For example, the lengths of the left and right waveguides in the drawing surface are changed by the bent waveguide 11, that is, the phase corresponding to the amount of light traveling is changed. Furthermore, the directional coupler 10A is given a wavelength characteristic with a certain period, and the directional coupler 10B is given a wavelength characteristic with a period different from that of the directional coupler 10A. By adjusting these, the characteristic shape of the reflectance of the loop mirror 6 can be a convex shape.

Note that, in the loop mirror 6, by further adding the bent waveguide and a directional coupler in addition to the directional coupler 10A, the bent waveguide 11, and the directional coupler 10B, the degree of freedom in adjusting the reflection characteristic increases. For example, it is possible to achieve a loop mirror such as a bandpass filter regarding the wavelength of light, in which light of a certain wavelength is reflected by 100% and light of another wavelength is not reflected at all.

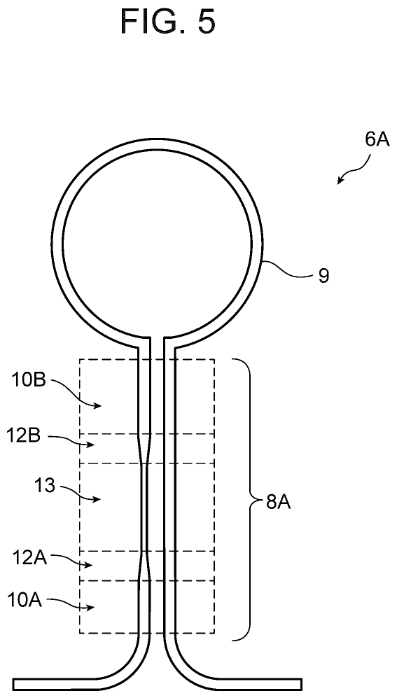

FIG. 5 is a plan view illustrating a loop mirror 6A that is Modification (1) of the loop mirror 6 in the first embodiment. The loop mirror 6A includes the directional coupler 10A, the directional coupler 10B, a propagation constant converting waveguide 12A, an uncoupled waveguide 13, and a propagation constant converting waveguide 12B. The loop waveguide 9 is a waveguide formed in a loop shape, and is optically coupled to the directional coupler 10B. As surrounded by a broken line in FIG. 5, the directional coupler 10A is a first directional coupler including waveguides adjacent to each other and having the same width. The directional coupler 10B is a second directional coupler having the same waveguide width as the directional coupler 10A, and includes waveguides adjacent to each other and having the same width. Further, in the directional coupler 10A and the directional coupler 10B, lengths of the waveguides are different from each other. For example, as illustrated in FIG. 5, the directional coupler 10B is formed to be longer than the directional coupler 10A. However, the lengths of the waveguides of the directional coupler 10A and the directional coupler 10B may be the same.

The uncoupled waveguide 13 includes waveguides, at least one waveguide of which has a waveguide width different from those of the directional coupler 10A and the directional coupler 10B. For example, as illustrated in FIG. 5, the uncoupled waveguide 13 has a waveguide width narrower than those of the directional coupler 10A and the directional coupler 10B. In the uncoupled waveguide 13, one of adjacent waveguides has a narrow waveguide width, and a distance between the waveguides is a distance at which optical coupling is not performed, that is, mode coupling is not performed.

The propagation constant converting waveguide 12A is a first propagation constant converting waveguide that is provided between the directional coupler 10A and the uncoupled waveguide 13 and whose waveguide width gradually changes from an end optically coupled to the directional coupler 10A to an end optically coupled to the uncoupled waveguide 13.

For example, as illustrated in FIG. 5, the propagation constant converting waveguide 12A is a tapered waveguide whose waveguide width gradually decreases from the end optically coupled to the directional coupler 10A to the end optically coupled to the uncoupled waveguide 13.

The propagation constant converting waveguide 12B is a second propagation constant converting waveguide that is provided between the uncoupled waveguide 13 and the directional coupler 10B and whose waveguide width gradually changes from an end optically coupled to the uncoupled waveguide 13 to an end optically coupled to the directional coupler 10B.

For example, as illustrated in FIG. 5, the propagation constant converting waveguide 12B is a tapered waveguide whose waveguide width gradually increases from the end optically coupled to the uncoupled waveguide 13 to the end optically coupled to the directional coupler 10B.

The propagation constant converting waveguide 12A and the propagation constant converting waveguide 12B are waveguides that adiabatically change a propagation constant of light. By changing the propagation constant of light, it is possible to generate a phase difference with an adjacent waveguide without using the bent waveguide 11. By using this, the characteristic shape of the reflectance of the loop mirror 6A can be a convex shape.

Note that the propagation constant converting waveguide 12A, the uncoupled waveguide 13, and the propagation constant converting waveguide 12B only need to be able to generate a phase difference with an adjacent waveguide. Thus, although an energy loss occurs, a multimode interference (MMI) waveguide that is non-adiabatic and changes a propagation constant may be used for the loop mirror 6A.

Note that the uncoupled waveguide 13 in FIG. 5 has a configuration in which the width of the waveguide on the left side of the drawing is narrowed, but the width of the waveguide on the right side of the drawing may be narrowed. By adjusting the width of a waveguide in this manner, the propagation constant of light can be changed even in the uncoupled waveguide 13.

In addition, in the uncoupled waveguide 13 in FIG. 5, the width of either the waveguide on either the left side of the drawing or the right side of the drawing may be wider than those of the directional couplers 10A and 10B. Even if the width of a waveguide is adjusted in this manner, the propagation constant of light can be changed even in the uncoupled waveguide 13.

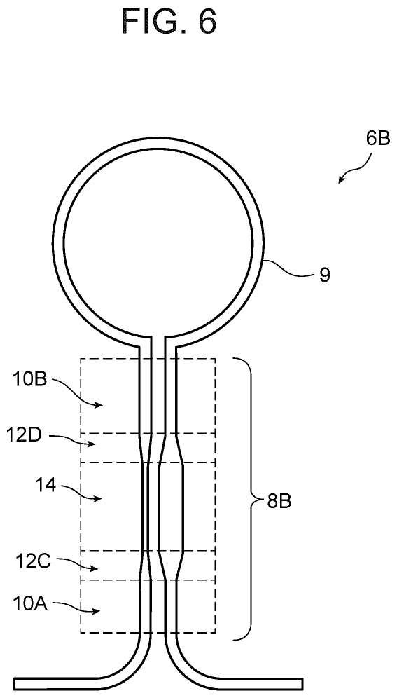

FIG. 6 is a plan view illustrating a loop mirror 6B that is Modification (2) of the loop mirror 6 in the first embodiment. The loop mirror 6B includes the directional coupler 10A, the directional coupler 10B, a propagation constant converting waveguide 12C, an uncoupled waveguide 14, and a propagation constant converting waveguide 12D. The loop waveguide 9 is a waveguide formed in a loop shape, and is optically coupled to the directional coupler 10B. As surrounded by a broken line in FIG. 6, the directional coupler 10A is a first directional coupler including waveguides adjacent to each other and having the same width. The directional coupler 10B is a second directional coupler having the same waveguide width as the directional coupler 10A, and includes waveguides adjacent to each other and having the same width. Further, in the directional coupler 10A and the directional coupler 10B, lengths of the waveguides are different from each other. For example, as illustrated in FIG. 6, the directional coupler 10B is formed to be longer than the directional coupler 10A. However, the lengths of the waveguides of the directional coupler 10A and the directional coupler 10B may be the same.

The uncoupled waveguide 14 includes waveguides, at least one waveguide of which has a waveguide width different from those of the directional coupler 10A and the directional coupler 10B. For example, as illustrated in FIG. 6, the uncoupled waveguide 14 has a waveguide width wider than those of the directional coupler 10A and the directional coupler 10B. In the uncoupled waveguide 14, one of adjacent waveguides has a wide waveguide width, and the other has a narrow waveguide width. Thus, the distance between the waveguides in the uncoupled waveguide 14 is not optically coupled, that is, a distance at which mode coupling is not performed.

The propagation constant converting waveguide 12C is a first propagation constant converting waveguide that is provided between the directional coupler 10A and the uncoupled waveguide 14 and whose waveguide width gradually changes from an end optically coupled to the directional coupler 10A to an end optically coupled to the uncoupled waveguide 14.

For example, as illustrated in FIG. 6, one of waveguides constituting the propagation constant converting waveguide 12C is a tapered waveguide in which the waveguide width gradually increases from an end optically coupled to the directional coupler 10A to an end optically coupled to the uncoupled waveguide 14. Furthermore, the other of the waveguides constituting the propagation constant converting waveguide 12C is a tapered waveguide in which the waveguide width gradually decreases from the end optically coupled to the directional coupler 10A to the end optically coupled to the uncoupled waveguide 14.

The propagation constant converting waveguide 12D is a second propagation constant converting waveguide that is provided between the uncoupled waveguide 14 and the directional coupler 10B and whose waveguide width gradually changes from an end optically coupled to the uncoupled waveguide 14 to an end optically coupled to the directional coupler 10B.

For example, as illustrated in FIG. 6, one of waveguides constituting the propagation constant converting waveguide 12D is a tapered waveguide in which the waveguide width gradually decreases from an end optically coupled to the directional coupler 10A to an end optically coupled to the uncoupled waveguide 14. Furthermore, the other of the waveguides constituting the propagation constant converting waveguide 12D is a tapered waveguide whose waveguide width gradually increases from an end optically coupled to the uncoupled waveguide 14 to an end optically coupled to the directional coupler 10B.

The propagation constant converting waveguide 12C and the propagation constant converting waveguide 12D are waveguides that adiabatically change a propagation constant of light. By changing the propagation constant of light, it is possible to generate a phase difference with an adjacent waveguide without using the bent waveguide 11. By using this, the characteristic shape of the reflectance of the loop mirror 6B can be a convex shape.

Note that the propagation constant converting waveguide 12C, the uncoupled waveguide 14, and the propagation constant converting waveguide 12D only need to be able to generate a phase difference with an adjacent waveguide. Thus, although an energy loss occurs, a multimode interference (MMI) waveguide that is non-adiabatic and changes a propagation constant may be used for the loop mirror 6B.

As described above, the multimode laser 1 according to the first embodiment includes the semiconductor amplifier 2, and the laser resonator 7 constituted between the loop mirror 6 including the waveguide formed on the semiconductor substrate 3 and the semiconductor amplifier 2. The characteristic shape of the reflectance of the loop mirror 6 is a convex shape in the oscillation wavelength range. The oscillation of a laser beam having a wavelength outside the oscillation wavelength range is suppressed, and thus the multimode laser 1 can suppress laser oscillation outside the oscillation wavelength range and can increase power efficiency.

In the multimode laser 1 according to the first embodiment, the semiconductor amplifier 2 includes an active layer of quantum dots. By employing the quantum dot semiconductor amplifier for the semiconductor amplifier 2, noise superimposed on a laser beam for each oscillation wavelength is reduced.

In the multimode laser 1 according to the first embodiment, the loop mirror 6 includes the directional coupler 10A that is waveguides adjacent to each other, the directional coupler 10B having the same waveguide width as the directional coupler 10A, the pair of waveguides provided between the directional coupler 10A and the directional coupler 10B, one of the waveguides being the bent waveguide 11, and the loop waveguide 9 optically coupled to the directional coupler 10B. By configuring the waveguide in this manner, it is possible to achieve the loop mirror 6 having a characteristic shape of reflectance that is a convex shape in the desired oscillation wavelength range.

In the multimode laser 1 according to the first embodiment, the loop mirror 6A or 6B includes the directional coupler 10A, the directional coupler 10B, the uncoupled waveguide 13 or 14, the propagation constant converting waveguide 12A or 12C provided between the directional coupler 10A and the uncoupled waveguide 13 or 14 and having a waveguide width gradually changing from an end optically coupled to the directional coupler 10A to an end optically coupled to the uncoupled waveguide 13 or 14, the propagation constant converting waveguide 12B or 12D provided between the uncoupled waveguide 13 or 14 and the directional coupler 10B and having a waveguide width gradually changing from an end optically coupled to the uncoupled waveguide 13 or 14 to an end optically coupled to the directional coupler 10B, and the loop waveguide 9 optically coupled to the directional coupler 10B. By adjusting the waveguide width in this manner, it is possible to achieve the loop mirror 6A or 6B having a reflectance characteristic shape that is a convex shape in the desired oscillation wavelength range.

In the multimode laser 1 according to the first embodiment, the uncoupled waveguide 13 includes a waveguide width narrower than those of the directional coupler 10A and the directional coupler 10B. In the propagation constant converting waveguide 12A, the waveguide width gradually decreases from the end optically coupled to the directional coupler 10A to the end optically coupled to the uncoupled waveguide 13. The propagation constant converting waveguide 12B has a waveguide width gradually increasing from the end optically coupled to the uncoupled waveguide 13 to the end optically coupled to the directional coupler 10B. By adjusting the waveguide width in this manner, it is possible to achieve the loop mirror 6A having a reflectance characteristic shape that is a convex shape in the desired oscillation wavelength range.

Further, even in a case where the uncoupled waveguide 13 includes a waveguide width wider than those of the directional coupler 10A and the directional coupler 10B, a similar effect can be obtained.

Note that, in the bent waveguide 11, light is easily radiated when the waveguide is bent and it is necessary to increase the bending radius of the waveguide in order to suppress the loss, and there are design restrictions. On the other hand, by changing the propagation constant by the uncoupled waveguide 13, it is possible to generate a phase difference with an adjacent waveguide without using a bent waveguide, and the degree of freedom in design increases.

In the multimode laser 1 according to the first embodiment, in the uncoupled waveguide 14, one of the adjacent waveguides has a waveguide width wider than those of the directional coupler 10A and the directional coupler 10B, and the other of the adjacent waveguides has a waveguide width narrower than those of the directional coupler 10A and the directional coupler 10B. One of waveguides constituting the propagation constant converting waveguide 12C has a waveguide width gradually increasing from the end optically coupled to the directional coupler 10A to the end optically coupled to the uncoupled waveguide 14. Further, in the other of the waveguides constituting the propagation constant converting waveguide 12C, the waveguide width gradually decreases from the end optically coupled to the directional coupler 10A to the end optically coupled to the uncoupled waveguide 14. In one of waveguides constituting the propagation constant converting waveguide 12D, the waveguide width gradually decreases from the end optically coupled to the uncoupled waveguide 14 to the end optically coupled to the directional coupler 10B. Furthermore, the waveguide width of the other of the waveguides constituting the propagation constant converting waveguide 12D gradually increases from the end optically coupled to the uncoupled waveguide 14 to the end optically coupled to the directional coupler 10B.

By adjusting the waveguide width in this manner, it is possible to achieve the loop mirror 6B having a reflectance characteristic shape that is a convex shape in the desired oscillation wavelength range.

Note that the loop mirror 6B illustrated in FIG. 6 has a larger difference in waveguide width between the waveguides described on the left and right sides of the drawing than the loop mirror 6A illustrated in FIG. 5. Thus, the loop mirror 6B has a larger propagation constant difference between adjacent waveguides than the loop mirror 6A, so that a desired phase difference can be given with a short waveguide length, and the loop mirror can be further downsized.

### Second Embodiment

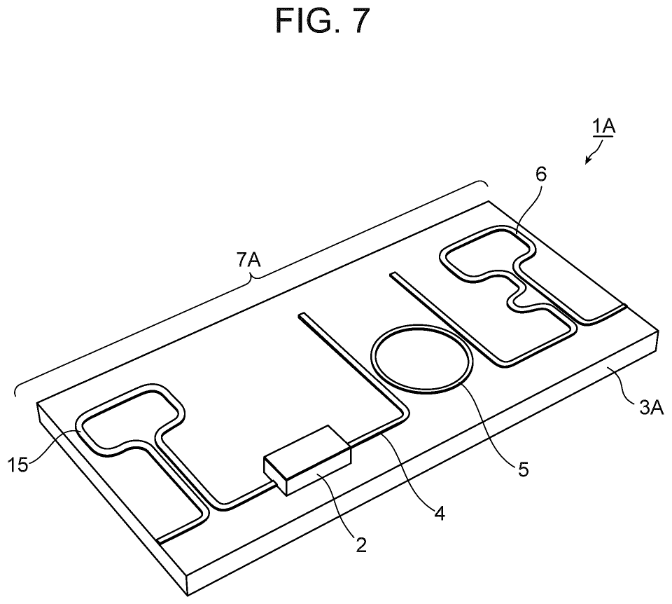

FIG. 7 is a perspective view illustrating a multimode laser 1A according to a second embodiment. The multimode laser 1A is a laser that emits a laser beam having wavelengths λ₁ to λ_{N} in the desired oscillation wavelength range. N is an integer of 2 or more. As illustrated in FIG. 7, the multimode laser 1A includes the semiconductor amplifier 2 and a semiconductor substrate 3A. The waveguides 4 are formed on the semiconductor substrate 3A, and waveguides 4 constitute the ring resonance filter 5, the loop mirror 6, and a loop mirror 15. A laser resonator 7A of the multimode laser 1A is constituted by disposing the semiconductor amplifier 2 between the loop mirror 6 and the loop mirror 15. Note that, in the semiconductor substrate 3A, the positions of the semiconductor amplifier 2 and the ring resonance filter 5 may be interchanged.

The front and rear surfaces of the semiconductor amplifier 2 are not subjected to HR coating and AR coating unlike the first embodiment, and are optically coupled to the waveguide 4 to allow light to enter and exit. By causing a current to flow through the semiconductor amplifier 2, spontaneous emission light generated in the semiconductor amplifier 2 is amplified as a seed. As the semiconductor amplifier 2, for example, a quantum dot semiconductor amplifier is used. The quantum dot semiconductor amplifier is an amplifier having less noise superimposed on the laser beam for each oscillation wavelength, and thus is suitable for the multimode laser 1A. Other types of semiconductor amplifiers can also be used for the multimode laser 1A. For example, a quantum well semiconductor amplifier may be used as the semiconductor amplifier 2.

The semiconductor substrate 3A is a substrate on which a waveguide for propagating light is formed. On the semiconductor substrate 3A, in addition to the waveguide 4 functioning as a transmission path of light, the ring resonance filter 5, the loop mirror 6, and the loop mirror 15 including a waveguide are integrally formed. The semiconductor substrate 3A is, for example, a silicon substrate, and the waveguide 4, the ring resonance filter 5, the loop mirror 6, and the loop mirror 15 are constituted by a silicon waveguide using the silicon photonics technology. Note that a silicon nitride (SiN) substrate may be used for the semiconductor substrate 3A. In addition, the waveguide may be an organic waveguide.

The loop mirror 6 is a first loop mirror in which a characteristic shape of reflectance is a convex shape in the desired oscillation wavelength range A. As does the ring resonance filter 5, the loop mirror 6 includes a waveguide formed on the semiconductor substrate 3A. As illustrated in FIG. 2, the loop mirror 6 is a Sagnac loop mirror including the MZ interferometer 8 and the loop waveguide 9.

The loop mirror 15 is a second loop mirror that substantially performs total reflection (reflectance close to 100%) in a wide wavelength band including the desired oscillation wavelength range A. As does the loop mirror 6, the loop mirror 15 includes a waveguide on the semiconductor substrate 3A, and constitutes the laser resonator 7A with the loop mirror 6.

In the multimode laser 1A, Fabry-Perot resonance occurs between the loop mirror 15 and the loop mirror 6 using spontaneous emission light generated by flowing a current through the semiconductor amplifier 2 as a seed. Light of a wavelength that can be passed by the ring resonance filter 5 in the laser resonator 7A is determined, and only the light of the passing wavelength oscillates by laser oscillation.

Note that, in the multimode laser 1, it is necessary to mount the semiconductor amplifier 2 and the semiconductor substrate 3 at accurate relative positions in order to optically couple the semiconductor amplifier 2 and the semiconductor substrate 3. That is, the multimode laser 1 has strict positional deviation tolerance required for laser oscillation.

On the other hand, in the multimode laser 1A, for example, a compound semiconductor part such as the semiconductor amplifier 2 can be manufactured by processing after bonding by a wafer bonding technique. In the multimode laser 1A, optical loss is suppressed by using optical coupling between waveguides, and laser oscillation with higher efficiency can be achieved.

Although the loop mirror 15 that performs total reflection in a wide wavelength band including the desired oscillation wavelength range A has been described so far, the loop mirror 15 may have a reflectance characteristic shape of a convex shape in the desired oscillation wavelength range A.

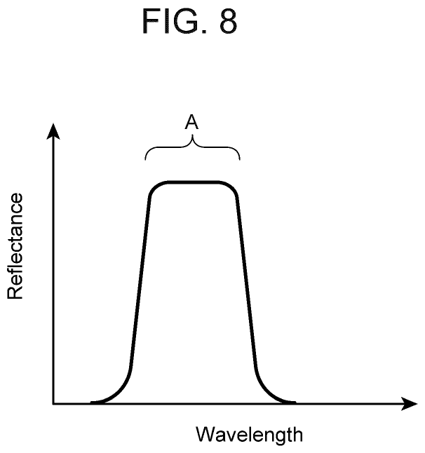

FIG. 8 is a graph illustrating a reflection characteristic of the loop mirror 15 in the second embodiment. As illustrated in FIG. 8, the loop mirror 15 may have the same structure as the loop mirror 6 illustrated in FIG. 2. In this case, the loop mirror 15 may have the same structure as the loop mirror 6A illustrated in FIG. 5 or the same structure as the loop mirror 6B illustrated in FIG. 6.

In the multimode laser 1A, the reflectance characteristic shapes of the loop mirror 6 and the loop mirror 15 are set to convex shapes in the desired oscillation wavelength range A. By adjusting the reflection characteristics of the loop mirror 6 and the loop mirror 15, it is possible to suppress oscillation of light having a wavelength that is difficult to oscillate or is not desired to oscillate in the laser resonator 7A. Note that light output from an end of the loop mirror 15 to the outside of the semiconductor substrate 3A is not used.

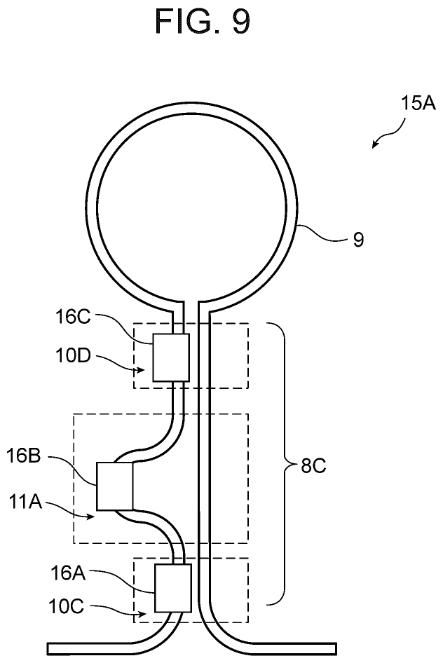

FIG. 9 is a plan view illustrating a loop mirror 15A that is Modification (1) of the loop mirror 15 in the second embodiment. As illustrated in FIG. 9, the loop mirror 15A includes the loop waveguide 9, a directional coupler 10C, a directional coupler 10D, and a bent waveguide 11A. The directional coupler 10C is provided with a phase adjusting unit 16A, the bent waveguide 11A is provided with a phase adjusting unit 16B, and the directional coupler 10D is provided with a phase adjusting unit 16C.

The loop waveguide 9 is a waveguide formed in a loop shape, and is optically coupled to the directional coupler 10D. As surrounded by a broken line in FIG. 9, the directional coupler 10C is a first directional coupler including waveguides adjacent to each other and having the same width. The directional coupler 10D is a second directional coupler having the same waveguide width as the directional coupler 10C, and includes waveguides adjacent to each other and having the same width. Further, in the directional coupler 10C and the directional coupler 10D, the lengths of the waveguides are different from each other. For example, as illustrated in FIG. 9, the directional coupler 10D is formed to be longer than the directional coupler 10C. In the pair of waveguides provided between the directional coupler 10C and the directional coupler 10D, one of the waveguides is the bent waveguide 11A.

The phase adjusting unit 16A adjusts the phase of light propagating through the directional coupler 10C. The phase adjusting unit 16B adjusts the phase of light propagating through the bent waveguide 11A. The phase adjusting unit 16C adjusts the phase of light propagating through the directional coupler 10D. Thus, the characteristic shape of the reflectance of the loop mirror 15A can be a convex shape in the desired oscillation wavelength range A.

The phase adjusting units 16A, 16B, and 16C are, for example, resistance elements that change the phase of light with heat when a current flows. In addition, the phase adjusting units 16A, 16B, and 16C may be diodes that change the refractive index by changing the density of carriers and change the phase of light accordingly. Note that the phase adjusting unit only needs to be provided in any of the directional coupler 10C, the directional coupler 10D, and the bent waveguide 11A. Furthermore, the phase adjusting units 16A, 16B, and 16C may be provided for the loop mirror 6.

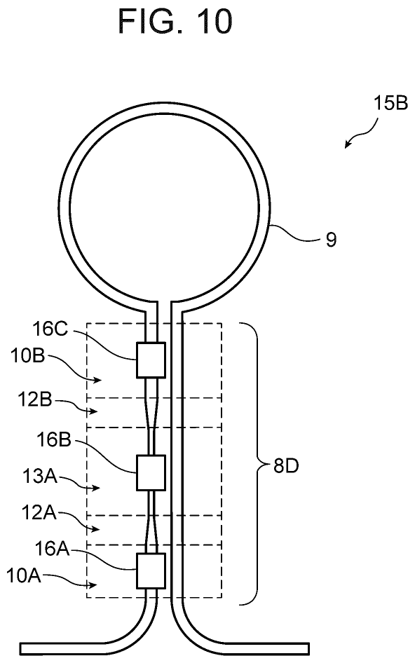

FIG. 10 is a plan view illustrating a loop mirror 15B that is Modification (2) of the loop mirror 15 in the second embodiment. As illustrated in FIG. 10, the loop mirror 15B includes the directional coupler 10A, the directional coupler 10B, the propagation constant converting waveguide 12A, an uncoupled waveguide 13A, and the propagation constant converting waveguide 12B. One of waveguides constituting the directional coupler 10A is provided with the phase adjusting unit 16A, one of waveguides constituting the uncoupled waveguide 13A is provided with the phase adjusting unit 16B, and one of waveguides constituting the directional coupler 10B is provided with the phase adjusting unit 16C.

Note that, unlike FIG. 10, the phase adjusting unit 16A may be provided in the other of the waveguides constituting the directional coupler 10A, the phase adjusting unit 16B may be provided in the other of the waveguides constituting the uncoupled waveguide 13A, and the phase adjusting unit 16C may be provided in the other of the waveguides constituting the directional coupler 10B.

The loop waveguide 9 is a waveguide formed in a loop shape, and is optically coupled to the directional coupler 10B. As indicated by a broken line in FIG. 10, the directional coupler 10A is a first directional coupler including waveguides adjacent to each other and having the same width. The directional coupler 10B is a second directional coupler having the same waveguide width as the directional coupler 10A, and includes waveguides adjacent to each other and having the same width. Further, in the directional coupler 10A and the directional coupler 10B, lengths of the waveguides are different from each other. For example, as illustrated in FIG. 10, the directional coupler 10B is formed to be longer than the directional coupler 10A. However, the lengths of the waveguides of the directional coupler 10A and the directional coupler 10B may be the same.

The phase adjusting unit 16A adjusts the phase of light propagating through the directional coupler 10A. The phase adjusting unit 16B adjusts the phase of light propagating through the uncoupled waveguide 13A. The phase adjusting unit 16C adjusts the phase of light propagating through the directional coupler 10B. Thus, the characteristic shape of the reflectance of the loop mirror 15B can be a convex shape in the desired oscillation wavelength range A.

The uncoupled waveguide 13A includes waveguides, at least one waveguide of which has a waveguide width different from those of the directional coupler 10A and the directional coupler 10B. For example, as illustrated in FIG. 10, the uncoupled waveguide 13A has a waveguide width narrower than those of the directional coupler 10A and the directional coupler 10B. In the uncoupled waveguide 13A, one of adjacent waveguides has a narrow waveguide width, and a distance between the waveguides is a distance at which optical coupling is not performed, that is, mode coupling is not performed.

The propagation constant converting waveguide 12A is a first propagation constant converting waveguide that is provided between the directional coupler 10A and the uncoupled waveguide 13A, and has a waveguide width that gradually changes from an end optically coupled to the directional coupler 10A to an end optically coupled to the uncoupled waveguide 13A.

For example, as illustrated in FIG. 10, the propagation constant converting waveguide 12A is a tapered waveguide whose waveguide width gradually decreases from the end optically coupled to the directional coupler 10A to the end optically coupled to the uncoupled waveguide 13A.

The propagation constant converting waveguide 12B is a second propagation constant converting waveguide that is provided between the uncoupled waveguide 13A and the directional coupler 10B and whose waveguide width gradually changes from an end optically coupled to the uncoupled waveguide 13A to the end optically coupled to the directional coupler 10B.

For example, as illustrated in FIG. 10, the propagation constant converting waveguide 12B is a tapered waveguide whose waveguide width gradually increases from the end optically coupled to the uncoupled waveguide 13A to the end optically coupled to the directional coupler 10B.

Note that the uncoupled waveguide 13A in FIG. 10 includes a configuration in which the width of the waveguide on the left side of the drawing is narrowed, but the width of the waveguide on the right side of the drawing may be narrowed. By adjusting the width of a waveguide in this manner, the propagation constant of light can be changed even in the uncoupled waveguide 13A.

In addition, in the uncoupled waveguide 13A in FIG. 10, the width of either the waveguide on either the left side of the drawing or the right side of the drawing may be wider than those of the directional couplers 10A and 10B. Even if the width of a waveguide is adjusted in this manner, the propagation constant of light can be changed even in the uncoupled waveguide 13.

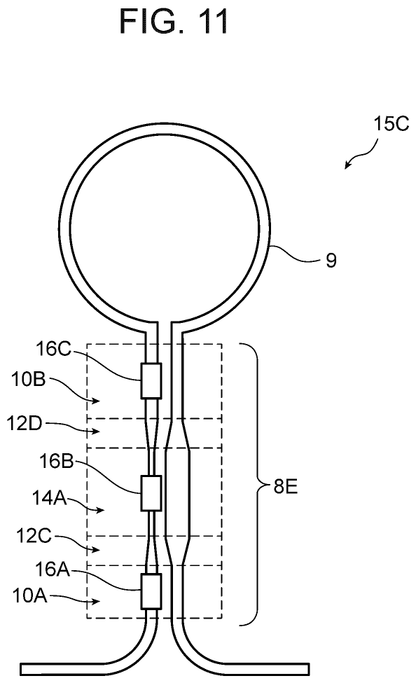

FIG. 11 is a plan view illustrating a loop mirror 15C that is Modification (3) of the loop mirror 15 in the second embodiment. As illustrated in FIG. 11, the loop mirror 15C includes the directional coupler 10A, the directional coupler 10B, the propagation constant converting waveguide 12C, an uncoupled waveguide 14A, and the propagation constant converting waveguide 12D. One of waveguides constituting the directional coupler 10A is provided with the phase adjusting unit 16A, one of waveguides constituting the uncoupled waveguide 14A is provided with the phase adjusting unit 16B, and one of waveguides constituting the directional coupler 10B is provided with the phase adjusting unit 16C.

Note that, unlike FIG. 11, the phase adjusting unit 16A may be provided in the other of the waveguides constituting the directional coupler 10A, the phase adjusting unit 16B may be provided in the other of the waveguides constituting the uncoupled waveguide 14A, and the phase adjusting unit 16C may be provided in the other of the waveguides constituting the directional coupler 10B.

The loop waveguide 9 is a waveguide formed in a loop shape, and is optically coupled to the directional coupler 10B. As indicated by a broken line in FIG. 11, the directional coupler 10A is a first directional coupler including waveguides adjacent to each other and having the same width. The directional coupler 10B is a second directional coupler having the same waveguide width as the directional coupler 10A, and includes waveguides adjacent to each other and having the same width. Further, in the directional coupler 10A and the directional coupler 10B, lengths of the waveguides are different from each other. For example, as illustrated in FIG. 11, the directional coupler 10B is formed to be longer than the directional coupler 10A. However, the lengths of the waveguides of the directional coupler 10A and the directional coupler 10B may be the same.

The uncoupled waveguide 14A includes waveguides, at least one waveguide of which has a waveguide width different from those of the directional coupler 10A and the directional coupler 10B. For example, as illustrated in FIG. 11, the uncoupled waveguide 14A has a waveguide width wider than those of the directional coupler 10A and the directional coupler 10B. In the uncoupled waveguide 14A, one of adjacent waveguides has a wide waveguide width, and the other has a narrow waveguide width. Thus, the distance between the waveguides in the uncoupled waveguide 14A is not optically coupled, that is, a distance at which mode coupling is not performed.

The propagation constant converting waveguide 12C is a first propagation constant converting waveguide that is provided between the directional coupler 10A and the uncoupled waveguide 14A and has a waveguide width gradually changing from an end optically coupled to the directional coupler 10A to an end optically coupled to the uncoupled waveguide 14A.

For example, as illustrated in FIG. 11, one of waveguides constituting the propagation constant converting waveguide 12C is a tapered waveguide in which the waveguide width gradually increases from the end optically coupled to the directional coupler 10A to the end optically coupled to the uncoupled waveguide 14A. Furthermore, the other of the waveguides constituting the propagation constant converting waveguide 12C is a tapered waveguide in which the waveguide width gradually decreases from the end optically coupled to the directional coupler 10A to the end optically coupled to the uncoupled waveguide 13.

The propagation constant converting waveguide 12D is a second propagation constant converting waveguide that is provided between the uncoupled waveguide 14A and the directional coupler 10B and whose waveguide width gradually changes from an end optically coupled to the uncoupled waveguide 14A to an end optically coupled to the directional coupler 10B.

For example, as illustrated in FIG. 11, one of waveguides constituting the propagation constant converting waveguide 12D is a tapered waveguide in which the waveguide width gradually decreases from the end optically coupled to the directional coupler 10A to the end optically coupled to the uncoupled waveguide 14A. Further, the other waveguide constituting the propagation constant converting waveguide 12D is a tapered waveguide in which the waveguide width gradually increases from an end optically coupled to the uncoupled waveguide 14A to an end optically coupled to the directional coupler 10B.

The phase adjusting unit 16A adjusts the phase of light propagating through the directional coupler 10A. The phase adjusting unit 16B adjusts the phase of light propagating through the uncoupled waveguide 14A. The phase adjusting unit 16C adjusts the phase of light propagating through the directional coupler 10B. Thus, the characteristic shape of the reflectance of the loop mirror 15C can be a convex shape in the desired oscillation wavelength range A.

As described above, the multimode laser 1A according to the second embodiment includes the semiconductor amplifier 2, and the laser resonator 7A constituted by disposing the semiconductor amplifier 2 between the loop mirror 6 and the loop mirror 15 including the waveguide formed on the semiconductor substrate 3A. The characteristic shape of the reflectance of the loop mirror 6 is a convex shape in the oscillation wavelength range. The oscillation of the laser beam having a wavelength other than the oscillation wavelength range is suppressed, and the multimode laser 1A can suppress the laser oscillation other than the oscillation wavelength range.

In the multimode laser 1A according to the second embodiment, the semiconductor amplifier 2 includes an active layer of quantum dots. By employing the quantum dot semiconductor amplifier for the semiconductor amplifier 2, noise superimposed on a laser beam for each oscillation wavelength is reduced.

In the multimode laser 1A according to the second embodiment, the laser resonator 7A includes the loop mirror 6. Thus, it is possible to provide the laser resonator 7A including the loop mirror 6 in which the characteristic shape of the reflectance is a convex shape in the desired oscillation wavelength range.

In the multimode laser 1A according to the second embodiment, the laser resonator 7A includes the loop mirror 6A or 6B. Thus, it is possible to provide the laser resonator 7A including the loop mirror 6 or 6B in which the characteristic shape of the reflectance is a convex shape in the desired oscillation wavelength range.

In the multimode laser 1A according to the second embodiment, the characteristic shape of the reflectance of the loop mirror 15 is a convex shape in the oscillation wavelength range. Thus, it is possible to provide the laser resonator 7A including the loop mirror 15 in which the characteristic shape of the reflectance is a convex shape in the desired oscillation wavelength range.

In the multimode laser 1A according to the second embodiment, the loop mirror 15 includes the directional coupler 10A that is waveguides adjacent to each other, the directional coupler 10B having the same waveguide width as the directional coupler 10A, the pair of waveguides provided between the directional coupler 10A and the directional coupler 10B, one of the waveguides being the bent waveguide 11, and the loop waveguide 9 optically coupled to the directional coupler 10B. By configuring the waveguide in this manner, it is possible to achieve the loop mirror 15 having a characteristic shape of reflectance that is a convex shape in the desired oscillation wavelength range.

In the multimode laser 1A according to the second embodiment, the loop mirror 15 includes the directional coupler 10A that is waveguides adjacent to each other, the directional coupler 10B having the same waveguide width as the directional coupler 10A, the uncoupled waveguide 13 or 14 in which at least one waveguide has a waveguide width different from those of the directional coupler 10A and the directional coupler 10B, the propagation constant converting waveguide 12A or 12C provided between the directional coupler 10A and the uncoupled waveguide 13 or 14 and having a waveguide width gradually changing from an end optically coupled to the directional coupler 10A to an end optically coupled to the uncoupled waveguide 13 or 14, and the propagation constant converting waveguide 12B or 12D provided between the uncoupled waveguide 13 or 14 and the directional coupler 10B and having a waveguide width gradually changing from an end optically coupled to the uncoupled waveguide 13 or 14 to an end optically coupled to the directional coupler 10B, and the loop waveguide 9 optically coupled to the directional coupler 10B. By adjusting the waveguide width in this manner, it is possible to achieve the loop mirror 15 having a characteristic shape of reflectance that is a convex shape in the desired oscillation wavelength range.

In the multimode laser 1A according to the second embodiment, in the uncoupled waveguide 13, one waveguide has a waveguide width narrower than those of the directional coupler 10A and the directional coupler 10B. In the propagation constant converting waveguide 12A, the waveguide width gradually decreases from the end optically coupled to the directional coupler 10A to the end optically coupled to the uncoupled waveguide 13. The propagation constant converting waveguide 12B has a waveguide width gradually increasing from the end optically coupled to the uncoupled waveguide 13 to the end optically coupled to the directional coupler 10B. By adjusting the waveguide width in this manner, it is possible to achieve the loop mirror 15 having a characteristic shape of reflectance that is a convex shape in the desired oscillation wavelength range.

Further, even in a case where the uncoupled waveguide 13 includes a waveguide width wider than those of the directional coupler 10A and the directional coupler 10B, a similar effect can be obtained.

Note that, in the bent waveguide 11, light is easily radiated when the waveguide is bent and it is necessary to increase the bending radius of the waveguide in order to suppress the loss, and there are design restrictions. On the other hand, by changing the propagation constant by the uncoupled waveguide 13, it is possible to generate a phase difference with an adjacent waveguide without using a bent waveguide, and the degree of freedom in design increases.

In the multimode laser 1A according to the second embodiment, in the uncoupled waveguide 14, one of the adjacent waveguides has a waveguide width wider than those of the directional coupler 10A and the directional coupler 10B, and the other of the adjacent waveguides has a waveguide width narrower than those of the directional coupler 10A and the directional coupler 10B. One of waveguides constituting the propagation constant converting waveguide 12C has a waveguide width gradually increasing from the end optically coupled to the directional coupler 10A to the end optically coupled to the uncoupled waveguide 14. Further, in the other of the waveguides constituting the propagation constant converting waveguide 12C, the waveguide width gradually decreases from the end optically coupled to the directional coupler 10A to the end optically coupled to the uncoupled waveguide 14. In one of waveguides constituting the propagation constant converting waveguide 12D, the waveguide width gradually decreases from the end optically coupled to the uncoupled waveguide 14 to the end optically coupled to the directional coupler 10B. Furthermore, the waveguide width of the other of the waveguides constituting the propagation constant converting waveguide 12D gradually increases from the end optically coupled to the uncoupled waveguide 14 to the end optically coupled to the directional coupler 10B.

By adjusting the waveguide width in this manner, it is possible to achieve the loop mirror 15 having a characteristic shape of reflectance that is a convex shape in the desired oscillation wavelength range.

Note that the loop mirror 15 having the same configuration as the loop mirror 6B illustrated in FIG. 6 has a larger difference in waveguide width between the waveguides described on the left and right sides of the drawing than that of the loop mirror 6A illustrated in FIG. 5. Thus, the loop mirror 15 having the same configuration as the loop mirror 6B has a larger propagation constant difference between adjacent waveguides than that having the same configuration as the loop mirror 6A, so that a desired phase difference can be given with a short waveguide length, and the loop mirror can be further downsized.

In the multimode laser 1A according to the second embodiment, the loop mirror 15A includes the phase adjusting units 16A, 16B, and 16C that are provided respectively in the bent waveguide 11A, the directional coupler 10C optically coupled to the bent waveguide 11A, and the directional coupler 10D optically coupled to the bent waveguide 11A, and adjust the phase of light propagating through the waveguide. The phase adjusting unit 16A adjusts the phase of light propagating through the directional coupler 10C, the phase adjusting unit 16B adjusts the phase of light propagating through the bent waveguide 11A, and the phase adjusting unit 16C adjusts the phase of light propagating through the directional coupler 10D. Thus, the characteristic shape of the reflectance of the loop mirror 15A can be a convex shape in the desired oscillation wavelength range A.

In the multimode laser 1A according to the second embodiment, the loop mirror 15B or 15C includes the phase adjusting units 16A to 16C provided in each of the uncoupled waveguide 13A or 14A, the directional coupler 10A, and the directional coupler 10B to adjust the phase of light propagating through the waveguide. Thus, the characteristic shape of the reflectance of the loop mirror 15B or 15C can be a convex shape in the desired oscillation wavelength range A.

Note that combinations of the individual embodiments, modifications of any components of the individual embodiments, or omissions of any components in the individual embodiments are possible.

Hereinafter, various aspects of the present disclosure will be collectively described as supplementary notes.

### Supplementary Note 1

A multimode laser including:
a semiconductor amplifier; and
a laser resonator constituted between a loop mirror including a waveguide formed on a substrate and the semiconductor amplifier, wherein
a characteristic shape of reflectance of the loop mirror is a convex shape in an oscillation wavelength range.

### Supplementary Note 2

The multimode laser according to supplementary note 1, in which
the semiconductor amplifier includes an active layer of quantum dots.

### Supplementary Note 3

The multimode laser according to supplementary note 1 or 2, in which
the loop mirror includes
a first directional coupler including waveguides adjacent to each other,
a second directional coupler having a same waveguide width as the first directional coupler,
a pair of waveguides provided between the first directional coupler and the
second directional coupler, one of the waveguides being a bent waveguide, and a loop waveguide optically coupled to the second directional coupler.

### Supplementary Note 4

The multimode laser according to supplementary note 1 or 2, in which
the loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

### Supplementary Note 5

The multimode laser according to supplementary note 4, in which
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

### Supplementary Note 6

The multimode laser according to supplementary note 4 or 5, in which
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

### Supplementary Note 7

A multimode laser including:
a semiconductor amplifier; and
a laser resonator comprising a first loop mirror and a second loop mirror constituted by waveguides formed on a semiconductor substrate, wherein the semiconductor amplifier is disposed therebetween, wherein
a characteristic shape of reflectance of the first loop mirror is a convex shape in an oscillation wavelength range.

### Supplementary Note 8

The multimode laser according to supplementary note 7, in which
the semiconductor amplifier includes an active layer of quantum dots.

### Supplementary Note 9

The multimode laser according to supplementary note 7 or 8, in which
the first loop mirror includes
a first directional coupler including waveguides adjacent to each other,
a second directional coupler having a same waveguide width as the first directional coupler,
a pair of waveguides provided between the first directional coupler and the second directional coupler, one of the waveguides being a bent waveguide, and
a loop waveguide optically coupled to the second directional coupler.

### Supplementary Note 10

The multimode laser according to supplementary note 7 or 8, in which
the first loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

### Supplementary Note 11

The multimode laser according to supplementary note 10, in which
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

### Supplementary Note 12

The multimode laser according to supplementary note 10 or 11, in which
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

### Supplementary Note 13

The multimode laser according to any one of supplementary notes 7 to 12, in which
a characteristic shape of reflectance of the second loop mirror is a convex shape in the oscillation wavelength range.

### Supplementary Note 14

The multimode laser according to supplementary note 13, in which
the second loop mirror includes
a first directional coupler including waveguides adjacent to each other,
a second directional coupler having a same waveguide width as the first directional coupler,
a pair of waveguides provided between the first directional coupler and the second directional coupler, one of the waveguides being a bent waveguide, and
a loop waveguide optically coupled to the second directional coupler.

### Supplementary Note 15

The multimode laser according to supplementary note 13, in which
the second loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

### Supplementary Note 16

The multimode laser according to supplementary note 15, in which
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

### Supplementary Note 17

The multimode laser according to supplementary note 15 or 16, in which
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

### Supplementary Note 18

The multimode laser according to supplementary note 9 or 14, further including:
a phase adjusting unit provided in each of the bent waveguide, the first directional coupler optically coupled to the bent waveguide, and the second directional coupler optically coupled to the bent waveguide to adjust a phase of light propagating through the waveguide.

### Supplementary Note 19

The multimode laser according to any one of supplementary notes 10 to 12 or supplementary notes 15 to 17, further including:
a phase adjusting unit provided in each of the uncoupled waveguide, the first directional coupler, and the second directional coupler to adjust a phase of light propagating through the waveguide.

### INDUSTRIAL APPLICABILITY

The multimode laser according to the present disclosure can be used, for example, as a high-output light source in optical communication.

### REFERENCE SIGNS LIST

1, 1A: multimode laser, 2: semiconductor amplifier, 2A: rear surface, 2B: emission surface, 3, 3A: semiconductor substrate, 4: waveguide, 5: ring resonance filter, 6, 6A, 6B, 15, 15A, 15B, 15C: loop mirror, 7, 7A: laser resonator, 8: MZ interferometer, 9: loop waveguide, 10A, 10B, 10C, 10D: directional coupler, 11, 11A: bent waveguide, 12A, 12B, 12C, 12D: propagation constant converting waveguide, 13, 14: uncoupled waveguide, 16A, 16B, 16C: phase adjusting unit

1. A multimode laser comprising:
a semiconductor amplifier; and
a laser resonator constituted between a loop mirror including a waveguide formed on a substrate and the semiconductor amplifier, wherein
a characteristic shape of reflectance of the loop mirror is a convex shape in an oscillation wavelength range, and
the loop mirror includes
a first directional coupler including waveguides adjacent to each other,
a second directional coupler having a same waveguide width as the first directional coupler,
a pair of waveguides provided between the first directional coupler and the second directional coupler, one of the waveguides being a bent waveguide, and
a loop waveguide optically coupled to the second directional coupler.

2. A multimode laser comprising:
a semiconductor amplifier; and
a laser resonator constituted between a loop mirror including a waveguide formed on a substrate and the semiconductor amplifier, wherein
a characteristic shape of reflectance of the loop mirror is a convex shape in an oscillation wavelength range, and
the loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

3. The multimode laser according to claim 1, wherein
the semiconductor amplifier includes an active layer of quantum dots.

4. The multimode laser according to claim 2, wherein
the semiconductor amplifier includes an active layer of quantum dots.

5. The multimode laser according to claim 2, wherein
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

6. The multimode laser according to claim 2, wherein
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

7. A multimode laser comprising:
a semiconductor amplifier; and
a laser resonator comprising a first loop mirror and a second loop mirror constituted by waveguides formed on a semiconductor substrate, wherein the semiconductor amplifier is disposed therebetween, wherein
a characteristic shape of reflectance of the first loop mirror is a convex shape in an oscillation wavelength range.

8. The multimode laser according to claim 7, wherein
the semiconductor amplifier includes an active layer of quantum dots.

9. The multimode laser according to claim 7, wherein
the first loop mirror includes
a first directional coupler including waveguides adjacent to each other,
a second directional coupler having a same waveguide width as the first directional coupler,
a pair of waveguides provided between the first directional coupler and the second directional coupler, one of the waveguides being a bent waveguide, and
a loop waveguide optically coupled to the second directional coupler.

10. The multimode laser according to claim 7, wherein
the first loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

11. The multimode laser according to claim 10, wherein
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

12. The multimode laser according to claim 10, wherein
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

13. The multimode laser according to claim 10, wherein
the uncoupled waveguide includes a waveguide having a waveguide width narrower than waveguide widths of the first directional coupler and the second directional coupler, and another waveguide having a waveguide width wider than waveguide widths of the first directional coupler and the second directional coupler,
the first propagation constant converting waveguide connected to the waveguide in the uncoupled waveguide has a waveguide width gradually decreasing from the end optically coupled to the first directional coupler to the end optically coupled to the uncoupled waveguide,
the second propagation constant converting waveguide connected to the waveguide in the uncoupled waveguide has a waveguide width gradually increasing from the end optically coupled to the uncoupled waveguide to the end optically coupled to the second directional coupler,
the first propagation constant converting waveguide connected to the another waveguide in the uncoupled waveguide has a waveguide width gradually increasing from an end optically coupled to the first directional coupler to an end optically coupled to the uncoupled waveguide, and
the second propagation constant converting waveguide connected to the another waveguide in the uncoupled waveguide has a waveguide width gradually decreasing from an end optically coupled to the uncoupled waveguide to an end optically coupled to the second directional coupler.

14. The multimode laser according to claim 7, wherein
a characteristic shape of reflectance of the second loop mirror is a convex shape in the oscillation wavelength range.

15. The multimode laser according to claim 14, wherein
the second loop mirror includes
a first directional coupler including waveguides adjacent to each other,
a second directional coupler having a same waveguide width as the first directional coupler,
a pair of waveguides provided between the first directional coupler and the second directional coupler, one of the waveguides being a bent waveguide, and
a loop waveguide optically coupled to the second directional coupler.

16. The multimode laser according to claim 14, wherein
the second loop mirror includes
a first directional coupler including waveguides adjacent to each other,
a second directional coupler having a same waveguide width as the first directional coupler,
an uncoupled waveguide including at least one waveguide having a waveguide width different from waveguide widths of the first directional coupler and the second directional coupler,
a first propagation constant converting waveguide provided between the first directional coupler and the uncoupled waveguide and having a waveguide width gradually changing from an end optically coupled to the first directional coupler to an end optically coupled to the uncoupled waveguide,
a second propagation constant converting waveguide provided between the uncoupled waveguide and the second directional coupler and having a waveguide width gradually changing from an end optically coupled to the uncoupled waveguide to an end optically coupled to the second directional coupler, and
a loop waveguide optically coupled to the second directional coupler.

17. The multimode laser according to claim 16, wherein
the uncoupled waveguide includes a waveguide having a waveguide width narrower than waveguide widths of the first directional coupler and the second directional coupler,
the first propagation constant converting waveguide has a waveguide width gradually decreasing from the end optically coupled to the first directional coupler to the end optically coupled to the uncoupled waveguide, and
the second propagation constant converting waveguide has a waveguide width gradually increasing from the end optically coupled to the uncoupled waveguide to the end optically coupled to the second directional coupler.

18. The multimode laser according to claim 16, wherein
the uncoupled waveguide includes a waveguide having a waveguide width wider than waveguide widths of the first directional coupler and the second directional coupler,
the first propagation constant converting waveguide has a waveguide width gradually increasing from an end optically coupled to the first directional coupler to an end optically coupled to the uncoupled waveguide, and
the second propagation constant converting waveguide has a waveguide width gradually decreasing from an end optically coupled to the uncoupled waveguide to an end optically coupled to the second directional coupler.

19. The multimode laser according to claim 9, further comprising:
a phase adjuster provided in each of the bent waveguide, the first directional coupler optically coupled to the bent waveguide, and the second directional coupler optically coupled to the bent waveguide to adjust a phase of light propagating through the waveguide.

20. The multimode laser according to claim 10, further comprising:
a phase adjuster provided in each of the uncoupled waveguide, the first directional coupler, and the second directional coupler to adjust a phase of light propagating through the waveguide.
